(19) United States
(12) Patent Application Publication
(10) Pub. No.: US 2025/0224710 A1
(43) Pub. Date: Jul. 10, 2025

(54) Industrial design measurement and control device and method of application

(71) Applicant: Shaanxi University of Technology, Hanzhong City (CN)

(72) Inventors: Jia Liu, Hanzhong City (CN); Chunlei Peng, Hanzhong City (CN); Fan Yang, Hanzhong City (CN); Feng Xu, Hanzhong City (CN)

(73) Assignee: Shaanxi University of Technology, Hanzhong City (CN)

(21) Appl. No.: 19/088,958

(22) Filed: Mar. 24, 2025

Related U.S. Application Data
(63) Continuation of application No. PCT/CN2024/125286, filed on Oct. 16, 2024.

(30) Foreign Application Priority Data
Aug. 26, 2024 (CN) 202411176027

(51) Int. Cl. G05B 19/4155

(52) U.S. Cl. CPC G05B 19/4155; G05B 2219/31449

(57) ABSTRACT

The present invention discloses an intelligent industrial design measurement and control device and method of application. The key points of the technical solution include the construction and application of an AIGC agile industrial design model, a human-machine collaborative design process, the construction of an application paradigm for industrial product generation scenarios, model optimization decisions based on cognitive analysis, and application case studies and verification. The AIGC model significantly improves design efficiency and innovation by rapidly generating and optimizing design solutions. Through precise demand analysis and optimization decisions, it ensures that the design solution is highly consistent with user expectations, thereby improving user satisfaction. Agile design methods and multiple iterative optimizations ensure that the design process is efficient and accurate, and improve design quality and reliability. Rapid generation and optimization of design solutions effectively shortens the product development cycle, thereby improving the company's market response speed and competitiveness.

### TECHNICAL FIELD

The present invention relates to the technical field of intelligent measurement and control devices, and in particular to an intelligent industrial design measurement and control device and method of application.

### BACKGROUND ART

AIGC agile industrial design relates to the application and development of agile methodology in the design process in the field of industrial design. This model focuses on rapid feedback, flexible response and teamwork to improve design efficiency and quality, and is a research hotspot in the current field of industrial design. The image generation function of AIGC realizes its main function based on the generative adversarial network GAN. The human-machine collaborative AIGC agile industrial design model plays a key decision-making role in the intelligent human-machine interactive collaborative system. It integrates the comprehensive decision-making of humans and intelligent systems, can quickly respond to interactive cognition, and achieve the interactive effect efficiently and accurately. Industrial design can drive the integration and optimization of the entire life cycle of Hanzhong's equipment manufacturing industry. The AIGC model goes deep into human-machine collaborative systems, optimizes human-machine task allocation, and quickly generates reference solutions based on the model's own efficient recognition and cognitive capabilities, thus shortening the design and manufacturing cycle and improving overall manufacturing capabilities. For this reason, we propose the following method and intelligent measurement and control device for industrial design.

### SUMMARY OF THE INVENTION

In view of the deficiencies in the prior art, the present invention provides an industrial design intelligent measurement and control device and application method to solve the problems raised in the background technology.

The above technical objectives of the present invention are achieved through the following technical solutions:

An industrial design method of application for an intelligent measurement and control device includes the construction and application of an AIGC agile industrial design model, a human-machine collaborative design process, an application paradigm for industrial product generation scenarios, model optimization decisions based on cognitive analysis, and application case studies and verification; wherein the construction and application of the AIGC agile industrial design model includes model construction and application scenario modeling. Model construction includes the following steps: S1: introducing AIGC (generative adversarial network GAN) to assist in industrial product design; S1.1: constructing an interactive design paradigm of behavior-scenario-product; and S1.2: establishing system modeling based on functional elements, using IDEF0 for functional models and IDEF8 for user interface modeling.

Preferably, the application scenario modeling further includes the following steps: S2: using the IDEF modeling method to describe the functions and user interface of the torque tester manufacturing system; S2.1: Analyze the multimodal form of information flow and construct a mapping model that runs through the product layer, interaction layer and user layer.

Preferably, the human-machine collaborative design process includes input and prompt word design, generation and optimization;
Input and prompt word design includes the following steps: S3:
determine the design intention input prompt words, creative sketches, and simple models; S3.1: perform logical analysis and semantic decomposition on the prompt words, encode and match the user's implicit cognitive elements and emotional images.

Preferably, the generation and optimization include the following steps: S4: using generative AI models such as Midjourney to generate a modeling result case library; S4.1: iteratively optimizing the generated graphic information through multiple-model machine learning and training; S4.2: building a multi-channel perception system to perform decision optimization on the generated results.

Preferably, the application paradigm construction of the industrial product generation scenario includes a practical application of the industrial design method; wherein the practical application of the industrial design method includes the following steps: S5: define the function and structural system of the design product and generate a design prototype; S5.1: combine the optimal AI model with design thinking to quickly generate design drawings; S5.2: build an agile industrial design model and obtain an optimized collaborative design method.

Preferably, the model optimization decision based on cognitive analysis includes the construction of a multi-channel perceptual system and sensory evaluation and decision-making; wherein the construction of the multi-channel perceptual system includes the following steps: S6: analyzing the process of converting perceptual representation into behavioral representation; S6.1: constructing synesthesia channels of color+shape, intention+shape; S6.2: performing machine learning and optimization analysis through the Midjourney model.

Preferably, the perceptual evaluation and decision-making includes the following steps: S7: setting a perceptual attribute set and defining quantitative perceptual preferences; S7.1: constructing a hesitant fuzzy perceptual evaluation matrix and performing expert evaluation; S7.2: applying a hierarchical clustering analysis method to make an optimization decision on color configuration.

Preferably, the application case study and verification includes the following steps: S8: selecting typical cases for application research; S8.1: demonstrating the usability of the model and optimizing the design method.

An intelligent measurement and control device includes a perception module, an appearance module, a machine learning module, a user interaction module, a multimodal model, an AIGC model, a decision module, and an evaluation module. The perception module is used to perceive the appearance of a device and user behavior information, and the module preliminarily collects user needs and device status through information processing and perception conversion; the appearance module is used to divide the appearance of the device into different module groups according to the information collected by the perception module, and analyze and design through perceptual intention extraction; the machine learning module is used to use the collected data for training, analyze the logical mapping relationship between the input form and the output result, and optimize the design; the user interaction module is used to analyze the user's intention through human-computer collaboration. The multimodal model is used to deal with the problem of prompt word design, perform semantic logic decomposition, and match it with the user's cognition to generate a preliminary design plan; the AIGC model is used to generate modeling renderings of equipment components, and machine learning is performed through creative sketches and simple models to generate detailed product shapes; the decision-making module is used to make preliminary and secondary decisions based on multi-channel elements and perceptual intentions, optimize the design goals, and ensure that the final design meets user needs; the evaluation module uses the Kansei-TOPSIS evaluation model to evaluate the color emotional quality deviation and similarity of the product color configuration plan to ensure that the product appearance design meets the user's perceptual needs.

In summary, the present invention mainly has the following beneficial effects:

Compared with the prior art, the present invention has the following beneficial effects:

The AIGC model significantly improves design efficiency and innovation by quickly generating and optimizing design solutions. It ensures that design solutions are highly consistent with user expectations and improves user satisfaction through precise demand analysis and optimized decisions. Agile design methods and multiple iterative optimizations ensure that the design process is efficient and accurate, and improves design quality and reliability. It quickly generates and optimizes design solutions, effectively shortens the product development cycle, and improves a company's market response speed and competitiveness.

### BRIEF DESCRIPTION OF THE DRAWINGS

FIG. 1 is a schematic diagram of a device module of the present invention;

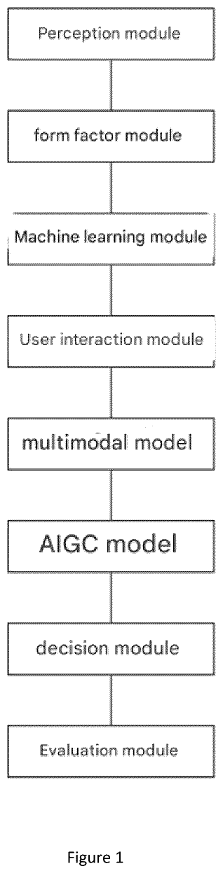

FIG. 2 is a schematic diagram of the process of the present invention.

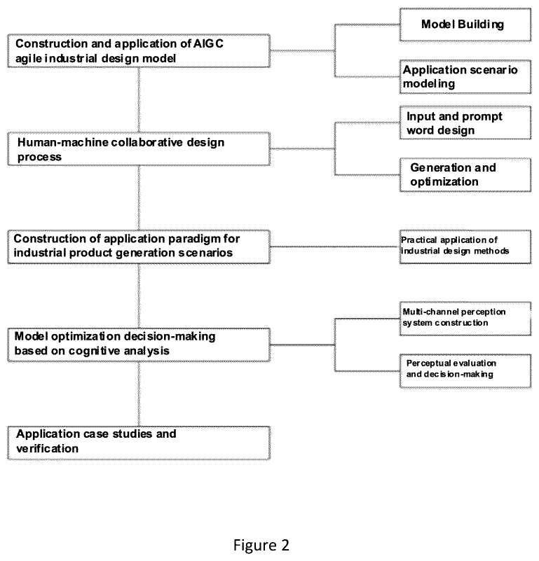

### DETAILED DESCRIPTION

In order to make the purpose, technical solution and advantages of the embodiments of the present invention clearer, the technical solution of the embodiments of the present invention will be clearly and completely described below in combination with the embodiments of the present invention. Obviously, the described embodiments are a subset of the embodiments of the present invention, rather than all the embodiments. Based on the described embodiments of the present invention, all other embodiments obtained by ordinary technicians in this field without creative work are within the scope of protection of the present invention.

The following examples are used to illustrate the present invention, but they cannot be used to limit the scope of protection of the present invention. The conditions in the examples can be further adjusted according to specific conditions. Simple improvements to the method of the present invention under the premise of the concept of the present invention belong to the scope of protection claimed in the present invention.

The technical solution of this patent is further described in detail below in conjunction with specific implementation methods.

### Embodiment 1

An industrial design application method for intelligent measurement and control devices, including the construction and application of AIGC agile industrial design model, human-machine collaborative design process, application paradigm construction of industrial product generation scenarios, model optimization decision-making based on cognitive analysis, and application case study and verification;
The construction and application of the AIGC agile industrial design model includes model construction and application scenario modeling;
The model construction includes the following steps:
S1: Introduce AIGC (Generative Adversarial Network GAN) to assist industrial product design;
S1.1: Construct the behavior-scenario-product interaction design paradigm;
S1.2: Establish system modeling based on functional elements, wherein IDEF0 is used for functional model, and IDEF8 is used for user interface modeling;
Quickly generate product shapes from creative ideas to improve design efficiency; optimize human-machine task allocation and shorten the design and manufacturing cycle;
The application scenario modeling comprises the following steps:
S2: Use IDEF modeling method to describe the functions and user interface of a torque tester manufacturing system;
S2.1: Analyze the multimodal forms of information flow and build a mapping model across the product layer, interaction layer, and user layer;
Reduce cognitive load, improve the efficiency and accuracy of product-human interaction; improve the smoothness of information flow, and optimize the interactive experience during the design process;
The human-computer collaborative design process includes input and prompt word design, generation and optimization;
The input and prompt word design comprises the following steps:
S3: Determine the design intention and input prompt words, creative sketches, and simple models;
S3.1: Logically analyze and decompose the prompt words, encode and match the user's implicit cognitive elements and emotional images;
The generation and optimization comprises the following steps:
S4: Use generative AI models such as Midjourney to generate a case library of modeling results;
S4.1: Iteratively optimize the generated graphical information through multiple machine learning and model training;
S4.2: Build a multi-channel perception system to optimize the decision-making of the generated results;
The construction of the application paradigm of the industrial product generation scenario includes the practical application of industrial design methods;
The practical application of the industrial design method comprises the following steps:
S5: Define the function and structural system of the design product and generate the design prototype;
S5.1: Optimize the combination of AI model and design thinking to quickly generate design drawings;
S5.2: Build an agile industrial design model and obtain optimized collaborative design methods;
The model optimization decision based on cognitive analysis includes the construction of multi-channel perception system and perceptual evaluation and decision-making;
wherein the multi-channel perception system construction includes the following steps:
S6: Analyze the process of converting perceptual representation into behavioral representation;
S6.1: Construct synesthesia channels color+shape, intention+shape;
S6.2: Machine learning and optimization analysis through the Midjourney model;
The perceptual evaluation and decision-making includes the following steps:
S7: Set the perceptual attribute set and define the quantitative perceptual preference;
S7.1: Construct hesitant fuzzy perceptual evaluation matrix for expert evaluation;
S7.2: Apply hierarchical cluster analysis to optimize color configuration decisions;
The application case study and verification includes the following steps:
S8: Select typical cases for applied research;
S8.1: Demonstrate the usability of the model and optimize the design method;
The two key concepts of cognitive theory are that information processing depends on the conversion of internal representation and psychological representation, that is, the conversion of perceptual representation into behavioral representation. Information processing is not a simple processing sequence from feeling to perception to memory. Perception is the key point to study and understand the process from information to modeling. Multi-channel perception can deeply analyze the internal causes of perception, so as to obtain the hidden elements of implicit perception. In the construction of product modeling, a synesthesia channel is constructed: the color+appearance channel; the perceptual reorganization channel: the intention+appearance channel, forming a multi-channel perceptual system of product appearance perception intention. In the appearance channel element, the appearance representation is divided into different module groups through structural modules for perceptual intention extraction. The grouping modules are imported into the Midjourney model respectively for machine learning to analyze the logical mapping relationship between the input form and the output result of information processing. From the perspective of the evolution of handwheel modeling, the cognition of handwheels starts from behavior. First, it has the function of guiding behavioral operations, that is, seeing the appearance, being able to process the information seen into perceptual information, and then transform it into behavioral guidance information through memory. Based on this principle, a decision is made on the product module modeling generated by AI. Secondary decision-making is based on the design goal to make a modeling decision. In the secondary decision-making, a classification decision is made according to the constructed multi-channel elements. The extraction method and results of perceptual intention are obtained. The hierarchical cluster analysis method is used for decision analysis. The steps are as follows: \textcircled{1} Establish a multimodal hierarchical original value matrix of product modeling, \textcircled{2} Data aggregation determines the distance matrix of multimodal cognitive channels, and \textcircled{3} Use Xsort to draw a tree diagram and classification results.

According to the theory of Kansei-TOPSIS evaluation model, the color emotional quality deviation and similarity of product color configuration schemes are evaluated, and the following four steps are set:

The first step is to set the scheme to a sample set A={Aᵢ, i=1, 2, . . . , 16, . . . , M}. Aᵢ is the sample corresponding to the Pantone color.

In the second step, the perceptual attribute set is set to C={Cⱼ, j=1, 2, . . . , 5, . . . , N}. Cⱼ is represented by a pair of bipolar perceptual adjectives K_{wj}=<k_{wj-}, k_{wj+}>, where k_{wj-} and k_{wj+} represent the left and right perceptual adjectives, respectively. Let the bipolar perceptual adjective set K_{W}={<k_{wj-},k_{wj+}>|j=1, 2, . . . , 5, . . . , N}. Thus, the perceptual intention vector table is set through expert review, and the color configuration is preliminarily optimized.

In the third step, combining the traditional semantic differential method and the hesitant fuzzy set proposed by Torra, the quantitative perceptual preference is defined according to expert discussion, allowing the membership of an element to be multiple different values and setting any value within an interval.

The fourth step is to collect the evaluation values of experts and construct the hesitant fuzzy perceptual evaluation matrix H′. The expert group E={Eᵢ, i=1, 2, . . . , k}, the experts score and evaluate the color configuration samples, and the hesitant fuzzy perceptual evaluation matrix H′=[h′ᵢⱼ]M×N is given by taking into account the overall opinions of the expert group, where h′ᵢⱼ is a hesitant fuzzy element, which represents the evaluation value of the scheme Aᵢ under the perceptual attribute Cⱼ.

### Embodiment 2

An intelligent measurement and control device includes a perception module, an appearance module, a machine learning module, a user interaction module, a multimodal model, an AIGC model, a decision module, and an evaluation module;
wherein, the perception module is used to perceive the appearance of the device and user behavior information. The module preliminarily collects user needs and device status through information processing and perception conversion;
the appearance module is used to divide the appearance of the device into different module groups according to the information collected by the perception module, and perform analysis and design through perceptual intention extraction;
the machine learning module is used to use the collected data for training, analyze the logical mapping relationship between the input form and the output result, and optimize the design;
the user interaction module is used to analyze the user's intention and design prompt words through human-computer collaboration to ensure that the design process meets the user's needs;
the multimodal model is used to handle the problem of prompt word design, perform semantic logic decomposition, match it with the user's cognition, and generate a preliminary design plan;
the AIGC model is used to generate modeling renderings of equipment components, and to generate detailed product shapes through machine learning through creative sketches and simple models;
the decision module is used to make preliminary and secondary decisions based on multi-channel elements and perceptual intentions, optimize the design goals, and ensure that the final design meets user needs; and,
the evaluation module uses the Kansei-TOPSIS evaluation model to evaluate the color emotional quality deviation and similarity of the product color configuration scheme to ensure that the product appearance design meets the user's emotional needs.

Although the embodiments of the present invention have been shown and described, it is understandable to those skilled in the art that, unless otherwise defined, the technical terms or scientific terms used in the present invention shall have the usual meanings understood by persons with ordinary skills in the field to which the present invention belongs. The words “including” or “comprising” and the like used in the present invention mean that the elements or objects appearing before the word include the elements or objects listed after the word and their equivalents, without excluding other elements or objects. The words “connect” or “connected” and the like are not limited to physical or mechanical connections, but may also include electrical connections, whether direct or indirect. “Up”, “down”, “left”, “right”, etc. are only used to indicate relative position relationships. When the absolute position of the described object changes, the relative position relationship may also change accordingly.

Although embodiments of the present invention have been shown and described, it will be appreciated by those skilled in the art that various changes, modifications, substitutions and variations may be made to the embodiments without departing from the principles and spirit of the present invention, and that the scope of the present invention is defined by the appended claims and their equivalents.

What is claimed is:

1. An industrial design method for designing intelligent measurement and control devices, comprising:
construction and application of an AIGC agile industrial design model;
construction and application of a human-machine collaborative design process;
construction and application of a paradigm for industrial product generation scenarios;
model optimization decision-making based on cognitive analysis; and,
application case study and verification;
wherein, the construction and application of the AIGC agile industrial design model includes model construction and application scenario modeling; wherein, the model construction includes the following steps:
S1: Introduce AIGC (Generative Adversarial Network GAN) to assist industrial product design;
S1.1: construct the behavior-scenario-product interaction design paradigm; and,
S1.2: establish system modeling based on functional elements, wherein IDEF0 is used for functional model and IDEF8 is used for user interface modeling;
wherein the application scenario modeling comprises the following steps:
S2: use IDEF modeling to describe the functions and user interface of a manufacturing system;
S2.1: analyze the multimodal forms of information flow and build a mapping model across a product layer, interaction layer, and user layer;
wherein the human-machine collaborative design process includes input and prompt word design, and, design generation and optimization;
wherein, the input and prompt word design comprises the following steps:
S3: determine the design intention and input prompt words, creative sketches, and simple models;
S3.1: perform logical analysis and semantic decomposition on the prompt words, encode and match the user's implicit cognitive elements and emotional images;
wherein the design generation and optimization comprises the following steps:
S4: use generative AI models such as Midjourney to generate a case library of modeling results;
S4.1: iteratively optimize the generated graphical information through multiple machine learning and model training;
S4.2: build a multi-channel perception system and optimize the decision-making of the generated results;
wherein the construction and application of a paradigm for industrial product generation scenarios includes implementing a practical application of the industrial design method;
wherein the implementing a practical application of the industrial design method comprises the following steps:
S5: define the function and structural system of a design product and generate a design prototype;
S5.1: optimize a combination of AI model and design thinking to quickly generate design drawings;
S5.2: build an agile industrial design model and obtain optimized collaborative design methods;
wherein the model optimization decision-making based on cognitive analysis includes construction of a multi-channel perception system and perceptual evaluation and decision-making;
wherein the construction of a multi-channel perception system includes the following steps:
S6: analyze the process of converting perceptual representation into behavioral representation;
S6.1: construct synesthesia channels color+shape, intention+shape;
S6.2: conduct machine learning and optimization through the Midjourney model;
wherein the perceptual evaluation and decision-making comprises the following steps:
S7: establish a perceptual attribute set and define a quantitative perceptual preference;
S7.1: construct a hesitant fuzzy perceptual evaluation matrix for expert evaluation;
S7.2: apply hierarchical cluster analysis to optimize color configuration decisions;
wherein the application case study and verification comprises the following steps:
S8: select typical cases for applied research;
S8.1: demonstrate the usability of the model and optimize the design approach.
